(19) United States
(12) Patent Application Publication
(10) Pub. No.: US 2006/0258128 A1
(43) Pub. Date: Nov. 16, 2006

(54) Methods and apparatus for enabling multiple process steps on a single substrate

(76) Inventors: Peter Nunan, Monte Sereno, CA (US); Anthony Renau, West Newbury, MA (US); Alan Sheng, Gloucester, MA (US); Paul Murphy, Reading, MA (US); Kyu-Ha Shim, Pelham, NH (US); Charles Teodorczyk, Danville, NH (US); Steven Anella, West Newbury, MA (US); Samuel Barsky, Wakefield, MA (US); Lawrence Ficarra, Billerica, MA (US); Richard J. Hertel, Boxford, MA (US)

Correspondence Address: Mark Superko,;Varian Semiconductor Equipment Associates, Inc., 35 Dory Road, Gloucester, MA, 01930, US

(21) Appl. No.: 11/329,761

(22) Filed: Jan. 11, 2006

Related U.S. Application Data
(60) Provisional application No. 60/660,420, filed on Mar. 9, 2005.

(51) Int. Cl. H01L 21/677; H01L 21/04

(52) U.S. Cl. 438/510; 414/217

(57) ABSTRACT

Substrate masking apparatus includes a platen assembly to support a substrate for processing, a mask having an aperture, a retaining mechanism to retain the mask in a masking position, and a positioning mechanism to change the relative positions of the mask and the substrate so that different areas of the substrate are exposed through the aperture in the mask. The apparatus may further include a mask loading mechanism to transfer the mask to and between the masking position and a non-masking position. The processing may include ion implantation of the substrate with different implant parameter values in different areas. In other embodiments, an area of the substrate to be processed is selectable by a mask, a shutter or a beam modifier in front of the substrate.

### CROSS-REFERENCE TO RELATED APPLICATIONS

This application claims the benefit of Provisional Application Ser. No. 60/660,420, filed Mar. 9, 2005, which is hereby incorporated by reference in its entirety.

### FIELD OF THE INVENTION

This invention relates to processing of substrates, such as semiconductor wafers, and, more particularly, to methods and apparatus for processing different areas of a substrate with different process parameters. The invention may be used for ion implantation of semiconductor wafers, but is not limited to ion implantation or to semiconductor wafers.

### BACKGROUND OF THE INVENTION

In conventional ion implantation, an entire wafer is implanted with a single set of implant parameter values such as dose, energy, dopant species and beam incidence angle. In most applications, uniform ion implantation over the surface of the semiconductor wafer is a requirement.

In the development of integrated circuits, it is frequently necessary to vary process conditions in order to determine optimum process and device parameter values. Design of experiments (DOE) in research and development and production facilities has required that a single wafer be used for each data point in an experiment. If a developer wants to conduct an experiment with multiple different parameter values, a number of wafers equal to the number of different parameter values is required. The cost of wafers, especially large diameter wafers, is prohibitive for optimizing process and device parameters. For example, 300 millimeter diameter wafers may cost $5,000 each.

Accordingly, there is a need for methods and apparatus for enabling multiple process steps to be performed on a single substrate, so that the number of substrates required for development of integrated circuits is reduced.

### SUMMARY OF THE INVENTION

According to a first aspect of the invention, substrate masking apparatus comprises a platen assembly to support a substrate for processing, a mask having an aperture, a retaining mechanism to retain the mask in a masking position, and a positioning mechanism to change the relative positions of the mask and the substrate, so that different areas of the substrate are exposed through the aperture in the mask.

In some embodiments, the processing comprises ion implantation of the substrate with different implant parameter values in different areas. The aperture in the mask defines an area of the substrate to be implanted using a specified set of implant parameter values.

According to a second aspect of the invention, a method is provided for processing a substrate. The method comprises positioning a mask having an aperture relative to a substrate so that a first area of the substrate is exposed through the aperture, processing the first area of the substrate through the aperture in the mask, changing the relative positions of the mask and the substrate so that a second area of the substrate is exposed through the aperture, and processing the second area of the substrate through the aperture in the mask.

According to a third aspect of the invention, a ion implanter comprises an ion beam generator to generate a ion beam, a platen assembly to support a substrate for ion implantation with the ion beam, a mask having an aperture, a mask loading mechanism to move the mask to a masking position, a retaining mechanism to retain the mask in the masking position, and a positioning mechanism to change the relative positions of the mask and the substrate so that different areas of the substrate are implanted by the ion beam passing through the aperture in the mask.

According to a fourth aspect of the invention, a method is provided for processing a substrate. The method comprises processing different areas of a substrate with different process parameter values. In some embodiments, the processing comprises ion implantation of the substrate with different implant parameter values.

According to a fifth aspect of the invention, ion implantation apparatus is provided. The ion implantation apparatus comprises a process chamber, an ion beam generator to generate an ion beam, a platen to support a substrate in the process chamber, and an implant control device to control ion implantation so that different areas of the substrate are implanted with different implant parameter values. The device may comprise a mask, a shutter or a beam modifier positioned in front of the substrate to define an area of the substrate to be implanted.

### BRIEF DESCRIPTION OF THE DRAWINGS

For a better understanding of the present invention, reference is made to the accompanying drawings, which are incorporated herein by reference and in which:

FIG. 1 is a simplified block diagram of an ion implantation system in accordance with a first embodiment of the invention;

FIG. 2 is a schematic illustration of the mask and wafer shown in FIG. 1;

FIG. 3 is a perspective view of substrate masking apparatus in accordance with a second embodiment of the invention;

FIG. 4 is a perspective view of substrate masking apparatus in accordance with a third embodiment of the invention;

FIG. 5 is a perspective view of substrate masking apparatus in accordance with a fourth embodiment of the invention;

FIG. 6 is a perspective view of substrate masking apparatus in accordance with a fifth embodiment of the invention;

FIG. 7 is a perspective view of substrate masking apparatus in accordance with a sixth embodiment of the invention;

FIG. 8 is a perspective view of substrate masking apparatus in accordance with a seventh embodiment of the invention;

FIG. 9 is a schematic diagram of a substrate handler that may be utilized with the substrate masking apparatus of the present invention;

FIG. 10 is a schematic diagram of the substrate handler utilized for handling both substrates and masks;

FIG. 11 is a perspective view of substrate masking apparatus in accordance with an eighth embodiment of the invention;

FIG. 12 is a perspective view that shows the substrate masking apparatus of FIG. 11 mounted in an ion implanter;

FIG. 13 is a simplified schematic block diagram of an ion implanter in accordance with a ninth embodiment of invention;

FIG. 14 is a perspective view of process control apparatus in accordance with a tenth embodiment of the invention; and

FIG. 15 is a simplified schematic block diagram of an ion implanter in accordance with an eleventh embodiment of the invention.

### DETAILED DESCRIPTION

Various process tools are used in the fabrication of substrates, such as semiconductor wafers. According to an aspect of the invention, a process tool, such as an ion implanter, is modified to process a selected area of a substrate. In some embodiments, the area of the substrate to be processed is selectable by a physical mask positioned in relation to the substrate, typically in front of and spaced from the substrate. Different areas of the substrate can be processed by repositioning the substrate, the mask, or both, and using two or more process steps. In further embodiments, the area of the substrate to be processed is selectable by a shutter positioned in relation to the substrate. The shutter may have an aperture that is variable in size and/or position. Different areas of the substrate can be processed by controlling the shutter, the substrate position, or both. In additional embodiments, the area of the substrate to be processed is selectable by modifying the ion beam, such as by blocking the ion beam during selected portions of an implant or by deflecting the ion beam away from the substrate during selected portions of an implant. Different process parameters can be used in different areas of the substrate. It will be understood that aspects of the present invention are directed to selectably processing macro areas of a substrate, such as areas each including multiple integrated circuits, in contrast to selectably processing microminiature features of individual integrated circuits.

There are several ways of implementing the process in an ion implanter. These techniques can be utilized in a single wafer architecture that uses a one or two dimensional scan, as well as in a batch architecture. In various ion implanter architectures, the ion beam is distributed over the substrate by beam scanning, by substrate movement or by a combination of beam scanning and substrate movement. The present invention may be utilized with any of these ion implanter architectures.

In one embodiment, a mask is positioned in front of a substrate, such as a semiconductor wafer. In this embodiment, the wafer is clamped on a holding mechanism such as a platen, either mechanically or electrostaically. A mask is positioned in front of the wafer. The mask has a cut out area, or aperture, which allows processing only through the aperture. The mask is movable between a masking position in front of the wafer and a non-masking position where the mask is removed from the wafer and has substantially no effect on wafer processing. The non-masking position may be a storage location inside or outside the process chamber. The processing system may utilize an automated mask loading and unloading mechanism as described below. In other embodiments, the mask may be mounted in the masking position manually.

In some embodiments, the mask loading and unloading mechanism moves the mask from a storage location within the vacuum chamber to the masking position in front of the wafer. A first area of the wafer is processed, such as by ion implantation, through the aperture in the mask. The wafer is then moved relative to the mask and a second area of the wafer is processed. The wafer can be repositioned, for example, by rotation on an orienter in a wafer handler. In other embodiments, the mask is repositioned relative to the wafer.

In further embodiments, the mask may be the size of a wafer and thus can be handled by the same wafer handling system that delivers the wafer to the process station. A series of masks can be placed in a FOUP (front opening unified pod), thereby allowing different masks to be delivered to and positioned accurately in front of the wafer, with a process step taking place after each mask change. By using different relative positions of the mask and the wafer, a single mask can be used to process two or more areas on the wafer. The wafer and/or the mask can be repositioned. The masks in the FOUP can be physically different and thus different areas of the wafer can be processed individually. This approach can be applied to single wafer ion implanters, including single and dual axis mechanical scan, and batch end stations in ion implanters, as well as process chambers in other semiconductor processing tools, such as sputtering, evaporation processes, CVD, etch, plasma cleaning systems, laser anneal, etc.

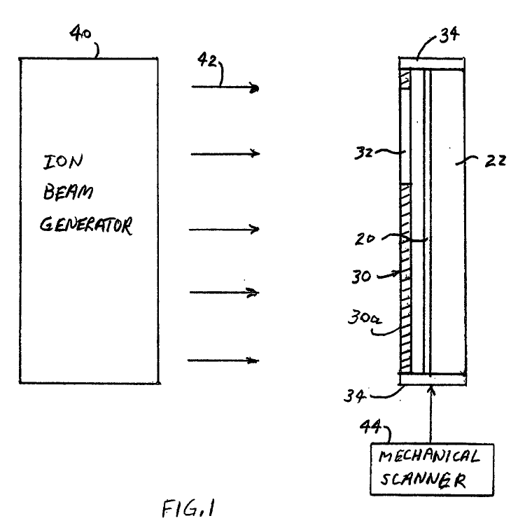

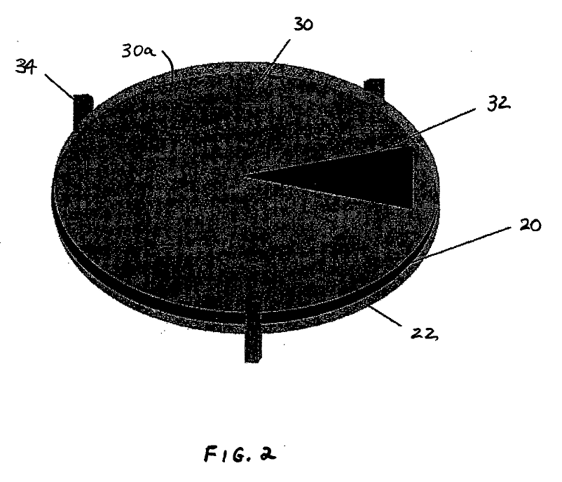

A simplified block diagram of an ion implanter in accordance with a first embodiment of the invention is shown in FIGS. 1 and 2. A semiconductor wafer 20 is mounted to a holding mechanism, or platen 22, such as an electrostatic wafer clamp or a mechanical wafer clamp. A mask 30 having an aperture at 32 is mounted in front of wafer 20 using retainers 34. Preferably, mask 30 is spaced from and does not physically contact wafer 20. In some embodiments, the spacing between mask 30 and wafer 20 is sufficient to permit wafer 20 to be loaded and unloaded from platen 22 without contacting mask 30. An ion beam generator 40 directs an ion beam 42 at wafer 20. Ion beam 42 may be a ribbon ion beam having a width at least as great as a diameter of wafer 20, may be a scanned ion beam (scanned in one or two dimensions) or may be a fixed ion beam. A mechanical scanner 44 may translate wafer 20 in one or two dimensions, depending on the configuration of ion beam 42 and the architecture of the ion implanter, so as to distribute ion beam 42 over the surface of wafer 20.

Mask 30 is configured to block ion beam 42, except in the area of aperture 32. Mask 30 thus has an ion beam blocking portion 30a and a non-blocking portion defined by aperture 32. Accordingly, wafer 20 is implanted only in the area defined by aperture 32. It will be understood that the implanted area of wafer 20 may exhibit edge effects in a region near the boundary of aperture 32. Mask 30 may include a single aperture 32 or two or more apertures. Aperture 32 may be located within the ion beam blocking portion 30a of mask 30, so that aperture 32 is surrounded by ion beam blocking portion 30a. In other embodiments, aperture 32 may be partially surrounded by ion beam blocking portion 30a. Thus, aperture 32 may have an interior location on mask 30 or may be located at the edge of mask 30. For example, mask 30 may have a circular shape with a sector-shaped aperture. In one specific example, mask 30 is circular and aperture 32 is a 90° sector.

The mask can be fabricated of a conductive material that minimizes contamination of the wafer being implanted. Suitable materials include carbon fiber, silicon carbide, silicon and graphite. A carbon fiber mask can have a thickness of 0.090 inch, for example. The aperture may have a relatively sharp edge to limit edge effects at the boundary between the mask material and the aperture. This mask information is given by way of example only and is not limiting as to the scope of the invention.

The relative positions of mask 30 and wafer 20 can be changed so as to implant different areas of wafer 20 through aperture 32. The repositioning can be achieved by reorienting wafer 20, by reorienting mask 30, or both. In other embodiments, different masks can be used to implant different areas of wafer 20. Each time a different area of wafer 20 is exposed, one or more parameter values of ion beam 42 can be changed. As a result, different areas of wafer 20 may be implanted with different implant parameter values.

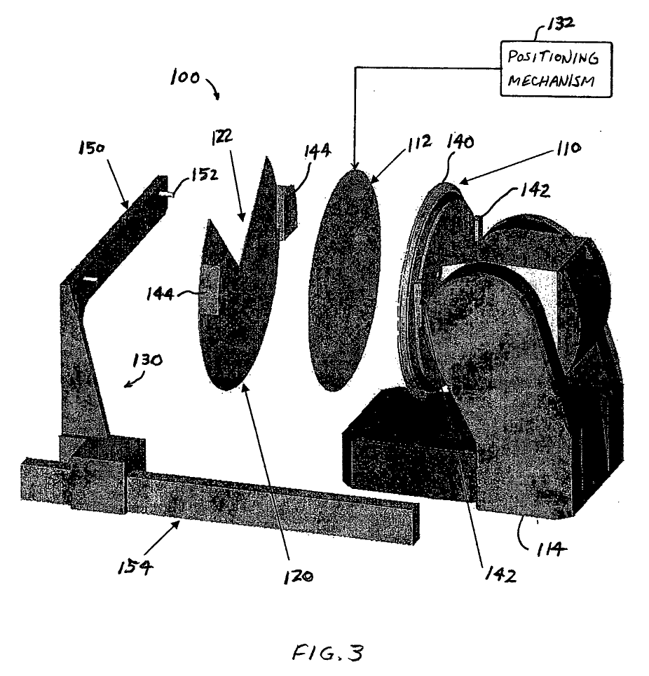

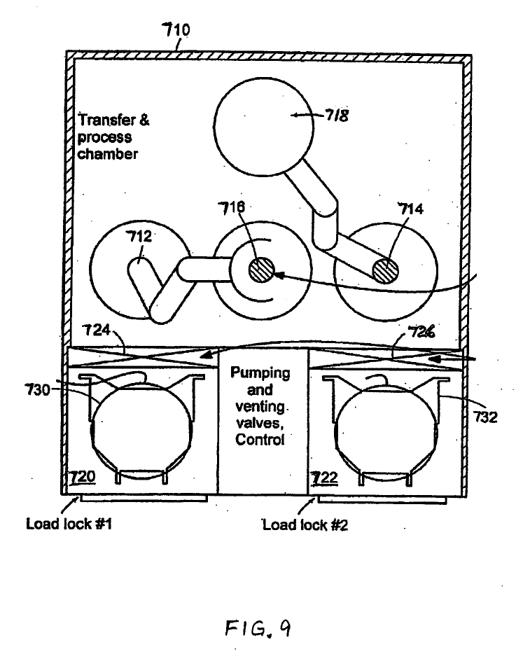

Substrate masking apparatus in accordance with a second embodiment of the invention is shown in FIG. 3. Substrate masking apparatus 100 includes a platen assembly 110 to support a substrate, such as a semiconductor wafer 112, for processing, such as by ion implantation. Platen assembly 110 is supported by a scan system 114. Substrate masking apparatus 100 further includes a mask 120 having an aperture 122, a mask loading mechanism 130 and a positioning mechanism 132 to change the relative positions of the mask 120 and the wafer 112. In the embodiment of FIG. 3, positioning mechanism 132 may be a wafer orienter that is part of a wafer handler, as described below in connection with FIG. 9.

Platen assembly 110 includes a platen 140 having a surface for supporting wafer 112 and an electrostatic clamp or a mechanical clamp for securing wafer 112 to platen 140. Platen assembly 110 may further include a cooling system for cooling wafer 112 during processing and a mechanism to rotate, or twist, wafer 112 about its central axis. In the embodiment of FIG. 3, platen assembly 110 includes mask retaining elements 142. As shown, mask 120 may be provided with fingers 144 for engaging mask retaining elements 142.

Platen assembly 110 is supported by scan system 114. Scan system 114 may tilt platen assembly 110 about a horizontal axis for angle implants and may rotate platen assembly 110 about the horizontal axis to a wafer load/unload position. In addition, scan system 114 may translate platen assembly 110 vertically during ion implantation.

In the embodiment of FIG. 3, mask loading mechanism 130 includes a transfer arm 150 having elements 152 for engaging mask 120 and a drive system 154 for moving transfer arm 150 between a load position and a storage position.

In operation, mask loading mechanism 130 moves mask 120 to and from the masking position in front of wafer 112 by operation of drive system 154. In the masking position, the mask 120 engages mask retaining elements 142. The mask loading mechanism 130 then retracts and the scan system 114 moves platen assembly 110 to the wafer load/unload position. Wafer 112 is then loaded under mask 120 by the wafer handling system shown in FIG. 9 and described below. The wafer 112 is then available to be implanted or otherwise processed. The wafer 112 is implanted in a first area defined by aperture 122 in mask 120. After the wafer has been implanted, it is removed by the wafer handling system. The wafer can be repositioned so that a second area of wafer 112 is exposed through aperture 122. The wafer can be repositioned, for example, by an orienter that is part of the wafer handler. After the selected areas of the wafer have been implanted, the wafer 112 can be removed and a new wafer can be loaded onto platen 140 for implantation. Mask 120 can remain in place or can be removed, depending on the desired mode of operation. The mask 120 can be removed by moving the transfer arm 150 to engage mask 120. Retaining elements 142 disengage mask 120, and transfer arm 150 retracts mask 120 to the storage position.

In an alternative operation, wafer 112 can be loaded onto platen 140 before the mask 120 is moved to the masking position.

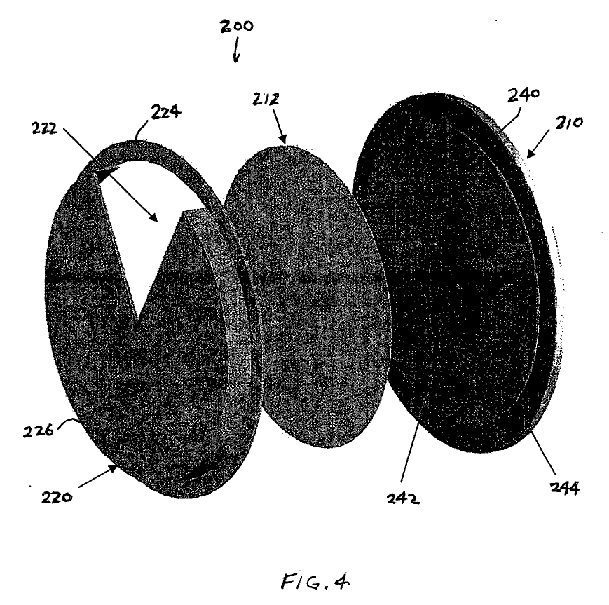

Substrate masking apparatus 200 in accordance with a third embodiment of the invention is shown in FIG. 4. The substrate masking apparatus 200 includes a platen assembly 210 and a mask 220. The scan system, the mask loading mechanism and the positioning mechanism are omitted from FIG. 4 for ease of illustration. Platen assembly 210 includes a platen 240 having an inner electrostatic clamp 242 for retaining a wafer 212 and an outer electrostatic clamp 244 for retaining mask 220. Mask 220 includes an aperture 222, a ring shaped region 224 that engages outer electrostatic clamp 244, and a raised central region 226 that is spaced from wafer 212.

The mask 220 may be moved to the masking position by a mask loading mechanism as described above or by a wafer handling system, as described below. Mask 220 is held in place in the masking position by outer electrostatic clamp 244. Wafer 212 is loaded onto platen 240, either before loading of mask 220 or through an appropriately dimensioned opening (not shown) in mask 220. Wafer 212 is held in place by inner electrostatic clamp 242. A first area of wafer 212 is then implanted or otherwise processed through aperture 222. The relative positions of wafer 212 and mask 220 are then changed to expose a second area of wafer 212 through aperture 222, and the second area of wafer 212 is implanted through aperture 222. As described above, the relative positions of wafer 212 and mask 220 may be changed by repositioning wafer 212, by repositioning mask 220, or both. This sequence is repeated until all desired areas of wafer 212 have been implanted.

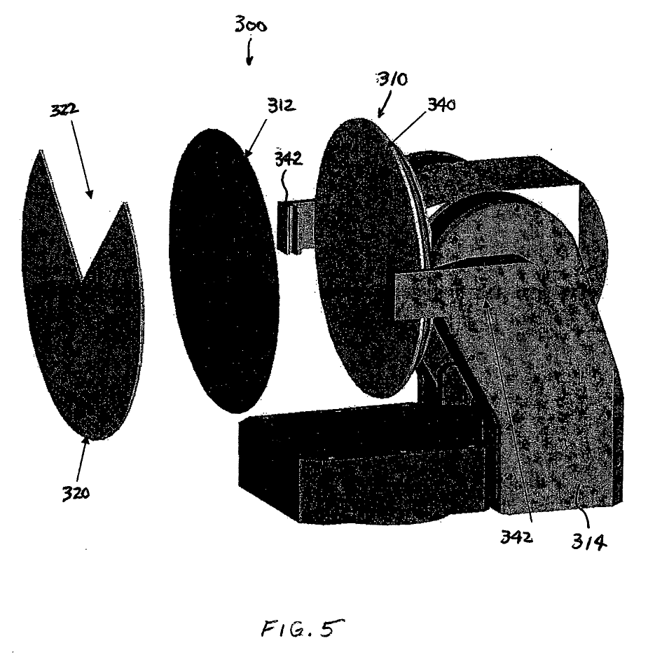

Substrate masking apparatus 300 in accordance with a fourth embodiment of the invention is shown in FIG. 5. Substrate masking apparatus 300 includes a platen assembly 310 supported by a scan system 314, and a mask 320 having an aperture 322. The mask loading mechanism and the positioning mechanism are omitted from FIG. 5 for ease of illustration. In the embodiment of FIG. 5, scan system 314 is provided with mask retaining elements 342. The mask retaining elements 342 maintain mask 320 in a fixed position as platen assembly 310 is tilted or rotated to the wafer load/unload position.

In operation, mask 320 can be moved to the masking position by a mask loading mechanism as described above or by a wafer handler as described below. In the masking position, mask 320 engages mask retaining elements 342. The mask loading mechanism retracts and the scan system 314 rotates platen assembly 310 to the wafer load/unload position. Wafer 312 is loaded onto platen 340 by the wafer handling system. A first area of wafer 312 is then implanted through aperture 322 in mask 320. After the first area of wafer 312 has been implanted, the relative positions of mask 320 and wafer 312 are changed to expose a second area of wafer 312 for implantation. After the selected areas of wafer 312 have been implanted, wafer 312 is removed by bringing the platen assembly 310 to the wafer load/unload position. The mask loading mechanism is moved to the load position to engage mask 320, and mask retaining elements 342 disengage mask 320. The mask 320 can be moved to a storage location when not in use. In an alternative operation, wafer 312 can be loaded onto platen 340 before mask 320 is moved to the masking position.

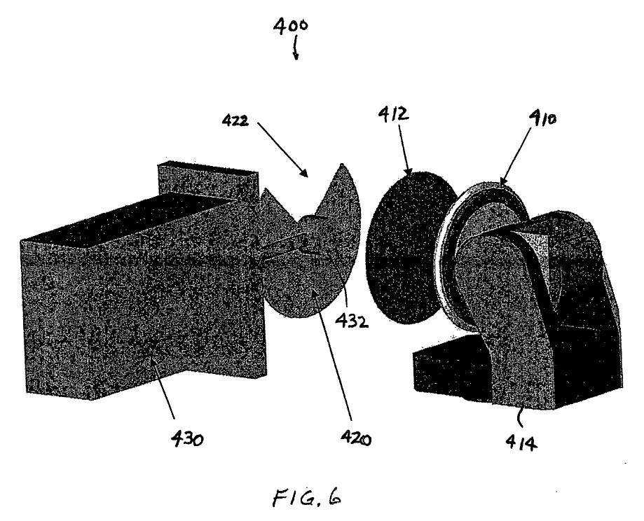

Substrate masking apparatus 400 in accordance with a fifth embodiment of the invention is shown in FIG. 6. Substrate masking apparatus 400 includes a platen assembly 410 supported by a scan system 414, a mask 420 having an aperture 422 and a mask loading mechanism 430. In the embodiment of FIG. 6, mask loading mechanism 430 positions mask 420 in the path of the ion beam during ion implantation. Mask loading mechanism 430 may retract mask 420 to a storage position out of the path of the ion beam. In addition, mask loading mechanism 430 may include a positioning mechanism 432 to rotate mask 420 relative to wafer 412. In other embodiments, different areas of wafer 412 can be exposed through aperture 422 by repositioning wafer 412. For example, wafer 412 can be repositioned by an orienter in the wafer handling system.

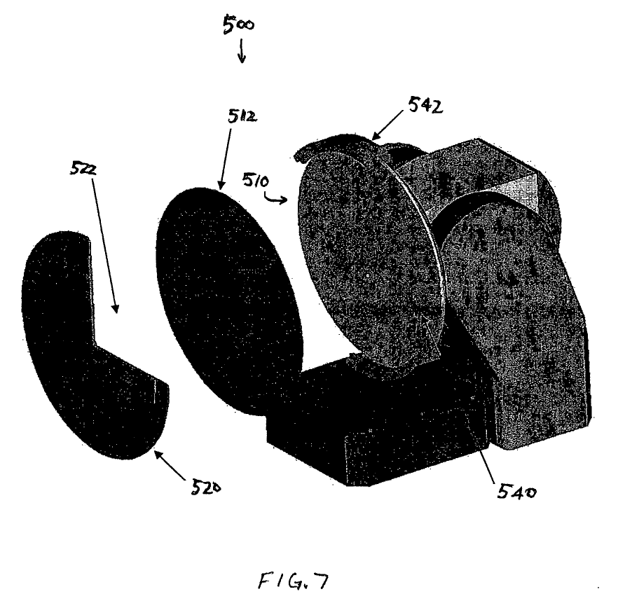

Substrate masking apparatus 500 in accordance with a sixth embodiment of the invention is shown in FIG. 7. The substrate masking apparatus 500 includes a platen assembly 510 supported by a scan system 514 and a mask 520 having an aperture 522. Platen assembly 510 is provided with mask retaining elements 542. In the embodiment of FIG. 7, mask 520 is manually loaded onto mask retaining elements 542. Wafer 512 may be loaded and unloaded by the wafer handling system and may be repositioned to expose different areas for implantation through aperture 522 in mask 520. Mask 520 may be removed manually from mask retaining elements 542 when use of mask 520 is not required.

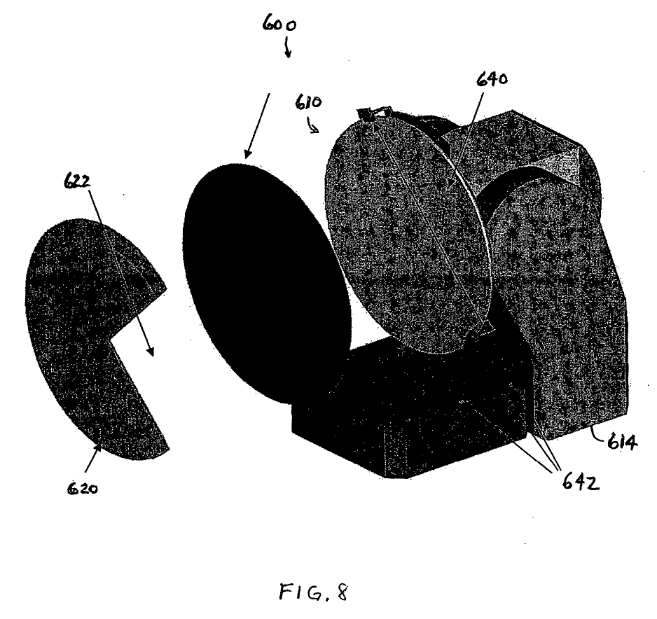

Substrate masking apparatus 600 in accordance with a seventh embodiment of the invention is shown in FIG. 8. Substrate masking apparatus 600 includes a platen assembly 610 supported by a scan system 614 and a mask 610 having an aperture 622. Platen assembly 610 includes a platen 640 and mask retaining elements 642. Mask 620 may be loaded manually onto mask retaining elements 642. The embodiment of FIG. 8 differs from the embodiment of FIG. 7 primarily with respect to the mask retaining elements. In the embodiment of FIG. 8, mask retaining elements 642 are moved between open and closed positions by twisting platen 640. The wafer retaining elements 642 are moved to the open position, mask 620 is loaded into the masking position and platen 640 is twisted so that mask retaining elements 642 engage mask 620. The process is reversed to remove mask 620 from the masking position.

A simplified schematic diagram of a wafer handling system suitable for operation with the substrate masking apparatus of FIGS. 3-8 is shown in FIG. 9. The wafer handling system may be of the type disclosed in U.S. Pat. No. 5,486,080, issued Jan. 23, 1996 to Sieradzki, which is hereby incorporated by reference. A vacuum chamber 710 contains a first robot 712, a second robot 714, a transfer station 716, or wafer orienter, and a platen assembly 718. Platen assembly 718 may correspond to the platen assemblies shown in FIGS. 3-8 and described above. Load locks 720 and 722 communicate with vacuum chamber 710 through isolation valves 724 and 726, respectively. Cassettes or FOUPs 730 and 732, each holding a plurality of semiconductor wafers, are placed in respective load locks 720 and 722.

In operation, a wafer is removed from FOUP 730 by the first robot 712 and is placed on transfer station 716. Transfer station 716 includes a wafer support and a position sensor, which determines the displacement error and the rotational error of the wafer with respect to reference values. Position sensing typically requires rotating the wafer with respect to the sensor. The rotational error is corrected by an appropriate rotation of the wafer support at transfer station 716. The wafer is then transferred to platen assembly 718 by second robot 714 with an appropriate adjustment to eliminate displacement error. After processing, the wafer is returned to FOUP 730 by first robot 712.

As described above, the wafer handler can reposition a wafer to expose different areas of the wafer for implantation through the aperture in the mask. This can be done by moving the wafer from platen assembly 718 to transfer station 716 and rotating the wafer by a prescribed amount. In the example where the aperture in the mask is a 90° sector, transfer station 716 can rotate the wafer by 90° after each implant. The wafer is then returned to platen assembly 718 for implantation of a different area through the aperture in the mask. Thus, transfer station 716 performs the function of wafer repositioning.

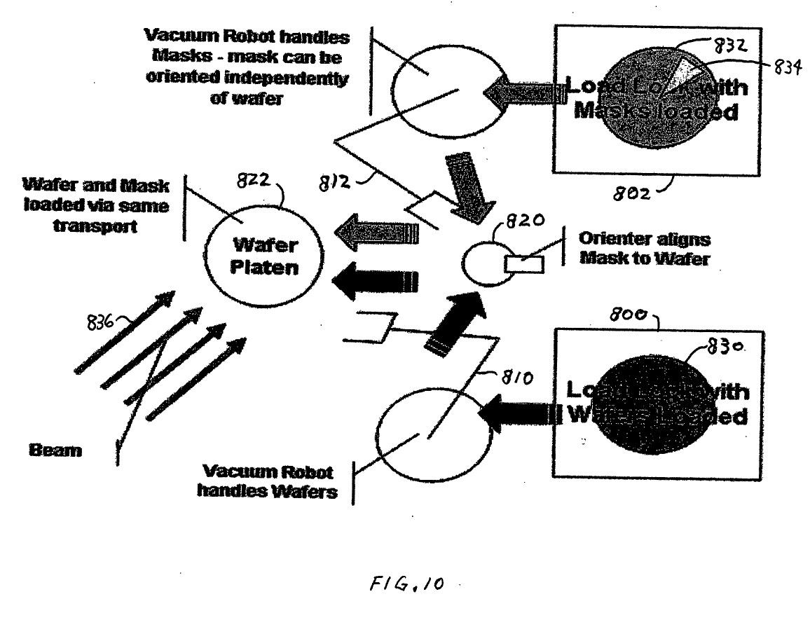

A simplified schematic diagram of a wafer handling system that in part implements an eighth embodiment of the invention is shown in FIG. 10. The wafer handling system may be generally of the type shown in FIG. 9 and described above. As shown, a first load lock 800 may be loaded with wafers 830 to be processed, and a second load lock 802 may be loaded with masks 832. A first robot 810 removes a wafer 830 from load lock 800 and places the wafer 830 at a transfer station 820 for orientation. The wafer is then transferred to a platen 822. A second robot 812 moves a mask 832 having an aperture 834 from load lock 802 to transfer station 820 for orientation. The mask 832 is then transferred to platen 822 and is placed in alignment with wafer 830, as described above. A first area of wafer 830 is then implanted with ion beam 836 through the aperture 834 in mask 832. The mask 832 can be moved from platen 822 to transfer station 820 for repositioning after the implant and then returned to platen 822 for implanting a second area of the wafer. Alternatively, the wafer 130 can be moved from platen 822 to transfer station 820 for repositioning after the implant and then returned platen 822 for implanting a second area of the wafer. This process can be repeated until the selected areas of wafer 830 have been implanted. Then, additional wafers can be loaded from load lock 800 for implantation. Similarly, masks with different aperture configurations and/or orientations can be loaded from load lock 802.

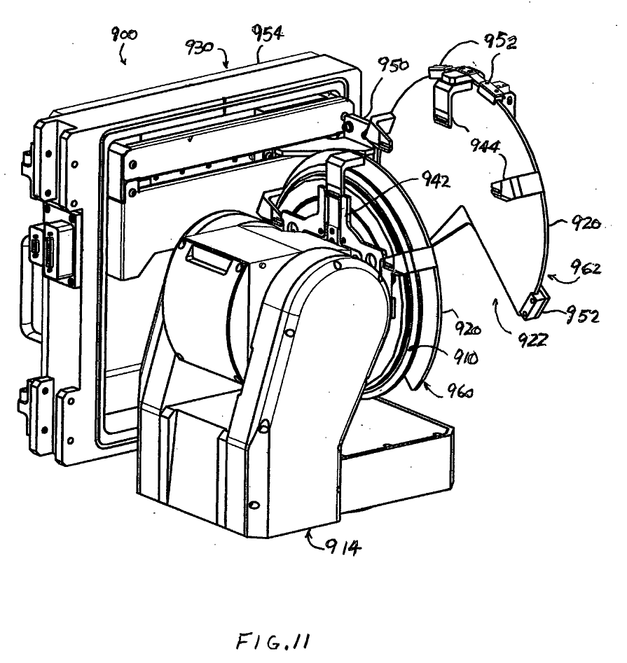

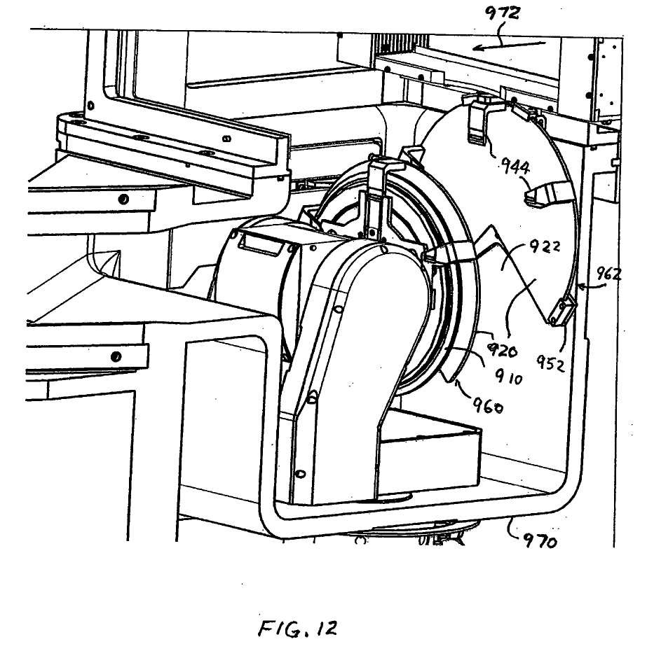

Substrate masking apparatus 900 in accordance with a ninth embodiment of the invention is shown in FIGS. 11 and 12. FIG. 11 illustrates substrate masking apparatus 900, while FIG. 12 illustrates substrate masking apparatus 900 in an ion implanter. Substrate masking apparatus 900 includes a platen assembly 910 supported by a scan system 914, a mask 920 having an aperture 922 and a mask loading mechanism 930. In each of FIGS. 11 and 12, mask 920 is shown both in a masking position 960 on platen assembly 910 and in a storage position 962 spaced from platen assembly 910. It will be understood that in an actual system, mask 920 is in only one position at any given time. As shown, platen assembly 910 is provided with mask retaining elements 942, and mask 920 is provided with fingers 944 that engage retaining elements 942 in the masking position. In particular, fingers 944 may snap into retaining elements 942.

Mask loading mechanism 930 may include a transfer arm 950 having mask clips 952, and a drive system 954. As shown, drive system 954 causes transfer arm 950 to move mask 920 to and between the masking position 960 and the storage position 962. The scan system 914 may move platen assembly 910 upwardly with respect to mask 920 so that fingers 944 on mask 920 snap into retaining elements 942.

As shown in FIG. 12, portions of the substrate masking apparatus 900 may be located in a housing 970 below a path traversed by ion beam 972. For ion implantation, scan system 914 translates platen assembly 910 and mask 920 vertically upward into the path of ion beam 972 to perform ion implantation. The mask loading mechanism 930 and the storage position 962 of mask 920 are spaced from the path of ion beam 972.

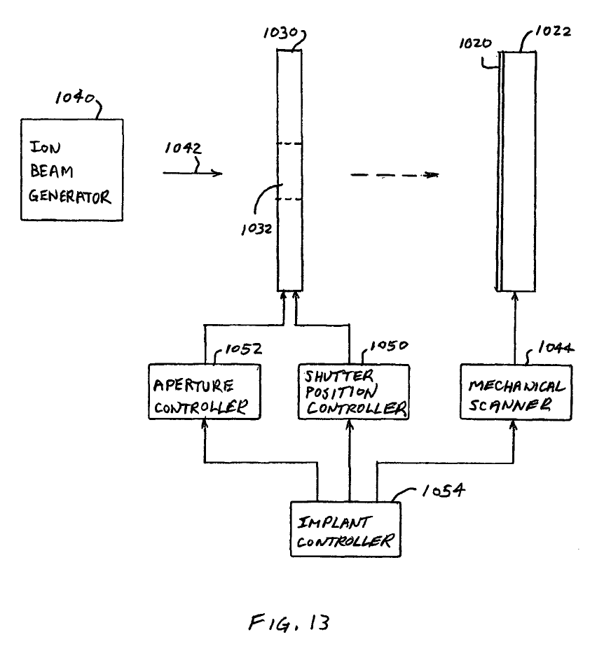

A simplified schematic block diagram of an ion implanter in accordance with a ninth embodiment of the invention is shown in FIG. 13. A semiconductor wafer 1020 is supported by a platen 1022, such as an electrostatic wafer clamp or mechanical wafer clamp. A shutter 1030 having an aperture 1032 is mounted in front of wafer 1020. An ion beam generator 1040 directs an ion beam 1042 at wafer 1020. Ion beam 1042 may be a ribbon beam having a width at least as great as a diameter of wafer 1020, may be a scanned ion beam (scanned in one or two dimensions) or may be fixed ion beam. A mechanical scanner 1044 may translate wafer 1020 in one or two dimensions, depending on the configuration of ion beam 1042 and the architecture of the ion implanter, so as to distribute ion beam 1042 over the surface of wafer 1020.

Shutter 1030 is configured to block ion beam 1042, except in the area of aperture 1032. Shutter 1030 may include a single aperture 1032 or two or more apertures. Shutter 1030 may have a variety of different configurations. In some embodiments, aperture 1032 may have a fixed size and shape. In other embodiments, aperture 1032 may be variable in one or two dimensions and may be variable in size and/or shape. Shutter 1030 may be configured so that aperture 1032 can be opened and closed. In addition, shutter 1030 may be configured to open aperture 1032 to a size that does not block ion beam 1042, thereby effectively disabling shutter 1030. In addition, shutter 1030 may be movable in one or two dimensions relative to ion beam 1042 and wafer 1020, so as to implant different areas of wafer 1020 through aperture 1032. Furthermore, shutter 1030 may be moved out of the path of ion beam 1042 when not required.

As shown in FIG. 13, the ion implanter may further include a shutter position controller 1050 to control the position of shutter 1030 relative to ion beam 1042, an aperture controller 1052 to control operation of aperture 1032 and an implant controller 1054 to control overall operation of the ion implanter. It will be understood that the shutter position controller 1050 is used in embodiments where the position of shutter 1030 is controllable and that aperture controller 1052 is used in embodiments where aperture 1032 is controllable. In various embodiments, selected areas of wafer 1020 may be implanted by controlling shutter 1030, by moving wafer 1020 relative to shutter 1030, or a combination thereof. Mechanical scanner 1044, shutter position controller 1050 and aperture controller 1052 may be controlled by implant controller 1054 to perform a desired implant.

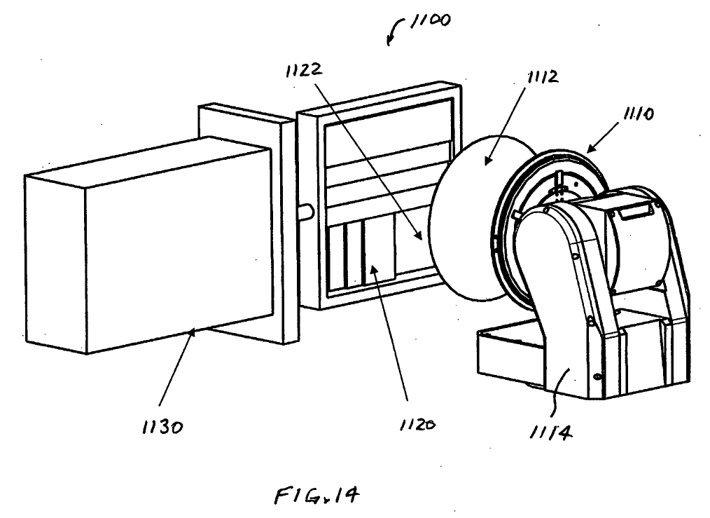

A perspective view of process control apparatus in accordance with a tenth embodiment of the invention is shown in FIG. 14. Process control apparatus 1100 includes a platen assembly 1110 to support a substrate, such as a semiconductor wafer 1112, for processing, such as by ion implantation. Platen assembly 1110 is supported by a scan system 1114. Process control apparatus 1100 further includes a shutter 1120 having an aperture 1122 and a shutter controller 1130. In the embodiment of FIG. 14, shutter controller 1130 may control the position of shutter 1120 relative to wafer 1112, may control aperture 1122, or both.

In operation, shutter controller 1130 positions shutter 1120 in front of wafer 1112 and sets a desired size, shape and position of aperture 1122. Wafer 1112 is loaded onto platen assembly 1110 by the wafer handling system shown in FIG. 9 and described above. Wafer 1112 is then available to be implanted or otherwise processed through aperture 1122. Wafer 1112 is implanted in a first area defined by aperture 1122. A second area of wafer 1112 can be implanted in one of several ways, depending on the configuration of the system. In one approach, shutter 1120 can be adjusted so that aperture 1122 is moved to expose a second area of wafer 1112 through the repositioned aperture. In another approach, wafer 1112 can be repositioned, for example, by an orienter that is part of the wafer handler as described above. After the selected areas of the wafer have been implanted, the wafer 1112 can be removed and a new wafer can be loaded onto platen assembly 1110.

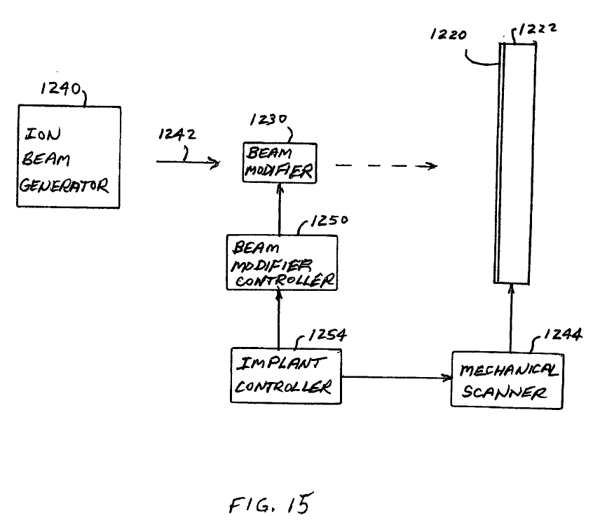

A simplified schematic block diagram of an ion implanter in accordance with an eleventh embodiment of the invention is shown in FIG. 15. A semiconductor wafer 1220 is supported by a platen 1222, such as an electrostatic wafer clamp or a mechanical wafer clamp. A beam modifier 1230 is mounted in front of wafer 1220. An ion beam generator 1240 directs an ion beam 1242 toward wafer 1220. Ion beam 1242 may be a ribbon ion beam having a width at least as great as a diameter of wafer 1220, may be a scanned ion beam (scanned in one or two dimensions) or may be a fixed ion beam. A mechanical scanner 1244 may translate wafer 1220 in one or two dimensions, depending on the configuration of ion beam 1242 and the architecture of the ion implanter, so as to distribute ion beam 1242 over the surface of wafer 1220.

Beam modifier 1230 is configured to modify ion beam 1242, so that ion beam 1242 implants wafer 1220 in one or more selected areas and is prevented from implanting wafer 1220 in other areas. In one embodiment, beam modifier 1230 may be a mechanical beam block that is moved into the path of ion beam 1242 during selected portions of an implant. In another embodiment, beam modifier 1230 is an electrostatic or magnetic deflector that can be energized to deflect ion beam 1242 away from wafer 1220 during selected portions of an implant. The ion inplanter further includes a beam modifier controller 1250 and an implant controller 1254.

In operation, implant controller 1254 controls mechanical scanner 1244 during an implant to distribute ion beam 1242 over wafer 1220. At specified times during the implant, implant controller 1240 may command beam modifier controller 1250 to inhibit ion beam 1242 from reaching wafer 1220 such as by blocking ion beam 1242 or deflecting ion beam 1242 away from wafer 1220. Thus, the process can be controlled to implant selected areas of wafer 1220.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. Substrate masking apparatus comprising:
a platen assembly to support a substrate for processing;
a mask having an aperture;
a retaining mechanism to retain the mask in a masking position; and
a positioning mechanism to change relative positions of the mask and the substrate so that different areas of the substrate are exposed through the aperture in the mask.

2. A substrate masking apparatus as defined in claim 1, wherein the retaining mechanism is affixed to the platen assembly.

3. A substrate masking apparatus as defined in claim 1, wherein the retaining mechanism is affixed to a scan system that supports the platen assembly.

4. A substrate masking apparatus as defined in claim 1, wherein the retaining mechanism and the mask include interengaging elements.

5. A substrate masking apparatus as defined in claim 1, wherein the retaining mechanism comprises an electrostatic clamp associated with the platen assembly.

6. A substrate masking apparatus as defined in claim 1, wherein the retaining mechanism is manually operable.

7. A substrate masking apparatus as defined in claim 1, wherein the mask is circular and has a sector-shaped opening.

8. A substrate masking apparatus as defined in claim 1, wherein the mask is spaced from the substrate to permit substrate loading and unloading on the platen assembly.

9. A substrate masking apparatus as defined in claim 1, wherein the substrate is repositioned so that different areas of the substrate are exposed through the aperture in the mask.

10. A substrate masking apparatus as defined in claim 1, wherein the mask is repositioned so that different areas of the substrate are exposed through the aperture in the mask.

11. A substrate masking apparatus as defined in claim 1, wherein the repositioning mechanism comprises a substrate orienter and a transfer mechanism to move the substrate to and between the platen assembly and the substrate orienter.

12. A substrate masking apparatus as defined in claim 1, further comprising a mask loading mechanism to load the mask onto the retaining mechanism.

13. Substrate masking apparatus as defined in claim 1, further comprising a mask loading mechanism to transfer the mask to and between the masking position and a non-masking position.

14. Substrate masking apparatus as defined in claim 13, wherein the mask loading mechanism serves as the retaining mechanism.

15. Substrate masking apparatus as defined in claim 14, wherein the mask loading mechanism serves as the positioning mechanism.

16. Substrate masking apparatus as defined in claim 13, wherein the mask loading mechanism includes a transfer arm and a drive assembly to move the transfer arm between the masking position and the non-masking position.

17. Substrate masking apparatus as defined in claim 1, further comprising a substrate handling mechanism to load and unload the substrate from the platen assembly.

18. Substrate masking apparatus as defined in claim 17, wherein the substrate handling mechanism loads and unloads the mask from the retaining mechanism.

19. A method for processing a substrate, comprising;
positioning a mask having an aperture relative to a substrate so that a first area of the substrate is exposed through the aperture;
processing the first area of the substrate through the aperture in the mask;
changing relative positions of the mask and the substrate so that a second area of the substrate is exposed through the aperture; and
processing the second area of the substrate through the aperture in the mask.

20. A method as defined in claim 19, wherein processing the first and second areas of the substrate comprises ion implanting the first and second areas of the substrate.

21. A method as defined in claim 20, wherein ion implanting the first and second areas of the substrate comprises changing at least one ion implant parameter between ion implanting the first area and ion implanting the second area.

22. A method as defined in claim 19, wherein positioning a mask relative to a substrate comprises positioning the substrate on a platen and positioning the mask in a masking position.

23. A method as defined in claim 22, wherein changing the relative positions of the mask and the substrate comprises moving the substrate to an orienter, rotating the substrate and moving the substrate from the orienter to the platen.

24. An ion implanter comprising;
an ion beam generator to generate an ion beam;
a platen assembly to support a substrate for ion implantation;
a mask having an aperture;
a mask loading mechanism to move the mask to a masking position;
a retaining mechanism to retain the mask in the masking position; and
a positioning mechanism to change relative positions of the mask and the substrate so that first and second areas of the substrate are implanted through the aperture in the mask.

25. A method for processing a substrate, comprising:
processing different areas of a substrate with different process parameter values.

26. A method as defined in claim 25, wherein processing different areas comprises ion implantation of different areas of a semiconductor wafer with different implant parameter values.

27. A method as defined in claim 26, wherein implanting different areas comprises implanting the wafer through a mask having an aperture which defines an area to be implanted.

28. A method as defined in claim 27, wherein implanting the wafer through a mask comprises changing an orientation of the mask relative to the wafer to expose different areas of the wafer for ion implantation.

29. A method as defined in claim 27, wherein implanting the wafer through a mask comprises changing masks to expose different areas of the wafer for ion implantation.

30. A method as defined in claim 27, further comprising moving the mask and the wafer to and from a platen with a substrate handler.

31. A method as defined in claim 30, further comprising changing the mask to a different mask with the substrate handler.

32. A method as defined in claim 30, further comprising changing the orientation of the mask relative to the wafer with the substrate handler.

33. Ion implantation apparatus comprising:
a process chamber;
an ion beam generator to generate an ion beam;
a holding mechanism to support a substrate in the process chamber; and
an implant control device to control ion implantation so that different areas of the substrate are implanted with different implant parameter values.

34. Ion implantation apparatus as defined in claim 33, wherein the implant control device comprises a mask positioned in front of the substrate, the mask having an aperture to define an area to be implanted.

35. Ion implantation apparatus as defined in claim 34, further comprising a substrate handler to move the mask and the substrate to and from the holding mechanism.

36. Ion implantation apparatus as defined in claim 35, wherein the substrate handler is configured to change masks to define different areas of the substrate to be implanted.

37. Ion implantation apparatus as defined in claim 35, wherein the substrate handler is configured to change the mask orientation relative to the substrate to define different areas of the substrate to be implanted.

38. Ion implantation apparatus as defined in claim 34, wherein the holding mechanism includes retainers for positioning the mask in spaced relation to the substrate.

39. Ion implantation apparatus as defined in claim 33, wherein the implant control device comprises a shutter positioned between the ion beam generator and the holding mechanism, the shutter having an aperture to pass the ion beam.

40. Ion implantation apparatus as defined in claim 39, wherein the shutter is movable.

41. Ion implantation apparatus as defined in claim 39, wherein the aperture in the shutter is adjustable.

42. Ion implantation apparatus as defined in claim 39, wherein the aperture in the shutter is closable.

43. Ion implantation apparatus as defined in claim 39, wherein the aperture in the shutter can be increased in size to pass the ion beam without substantial modification.

44. Ion implantation apparatus as defined in claim 33, wherein the implant control device comprises a beam modifier to modify the ion beam during selected portions of an implant.

45. Ion implantation apparatus as defined in claim 44, wherein the beam modifier comprises a beam block that is movable into and out of a path of the ion beam.

46. Ion implantation apparatus as defined in claim 44, wherein the beam modifier comprises a beam deflector to deflect the ion beam away from the substrate during a portion of the implant.
